(19) United States
(12) Patent Application Publication
(10) Pub. No.: US 2009/0015318 A1
(43) Pub. Date: Jan. 15, 2009

(54) CHARGE PUMP DRIVE CIRCUIT

(75) Inventor: Yuri HONDA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 12/172,565

(22) Filed: Jul. 14, 2008

(30) Foreign Application Priority Data
Jul. 12, 2007 (JP) 2007-183044

(51) Int. Cl. G11C 5/14

(52) U.S. Cl. 327/530

(57) ABSTRACT

A charge pump drive circuit includes a first MOSFET (Metal Oxide Semiconductor Field Effect Transistor) and a second MOSFET. The first MOSFET and the second MOSFET are different in channel type and provided to form a complementary inverter circuit. The complementary inverter circuit drives a charge pump circuit based on an input potential inputted to an input terminal. A first gate of the first MOSFET and a second gate of the second MOSFET are connected to the input terminal such that a potential at the first gate is different from a potential at the second gate.

### INCORPORATION BY REFERENCE

This application is based upon and claims the benefit of priority from Japanese patent application No. 2007-183044, filed on Jul. 12, 2007, the disclosure of which is incorporated herein in its entirely by reference.

### BACKGROUND OF THE INVENTION

1. Field of the Invention

The present invention relates to a charge pump drive circuit, a semiconductor device using the charge pump drive circuit and a voltage converting method, and especially relates to reduction of high-frequency noise in a charge pump circuit for stepping up or stepping down a direct current (DC) voltage.

2. Description of Related Art

A Dickson-type charge pump circuit is known as a charge pump circuit for stepping up or stepping down a DC voltage. Japanese Laid Open Patent Application (JP-P2006-340436A) discloses an example of such charge pump. Referring to FIG. 1, a step-up circuit using the Dickson-type charge pump circuit will be described.

Referring to FIG. 1, the charge pump circuit used for the step-up circuit includes five diodes Da to De connected in series between a power source Vi and an output terminal Vo, and five capacitors Ca to Ce. Ends (or nodes N1a to N1e) of the capacitors Ca to Ce are connected to anodes of the diodes Da to De, respectively. The other ends of the capacitors Ca and Cc are commonly connected via a node N2a to a charge pump drive circuit 100A which supplies a clock φ to the capacitors Ca and Cc. The other ends of the capacitors Cb and Cd are connected via a node N2b to a charge pump drive circuit 100B which supplies a clock φB to the capacitors Cb and Cd. The clock φB is opposite in phase to the clock φ. The other end of the capacitor Ce is connected to a ground (GND) as a second power source. The clock φ is a signal periodically repeating a high level (H) and a low level (L).

When the clock φ is at the low level, the nodes N1a and N1c are at the low level and the nodes N1b and N1d are at the high level. Accordingly, the diodes Da and Dc are in a conduction state and the diodes Db and Dd are in a non-conduction state. Thus, a source voltage Vi of the power source Vi is charged in the capacitor Ca and charge stored in the capacitor Cb flows into the capacitor Cc.

When the clock 4 is at the high level, the nodes N1a and N1c are at the high level and the nodes N1b and N1d are at the low level. Accordingly, the diodes Da and Dc are in the non-conduction state and the diodes Db and Dd are in the conduction state. Thus, a voltage which is higher than the voltage charged in the capacitor Ca by the source voltage Vi is charged in the capacitor Cb.

As described above, a voltage which is five times as large as the input voltage Vi appears at the output terminal Vo due to switching of the diodes Da to Dd and due to charging and discharging of capacitors Ca to Cd. Note that voltage drops in the diodes are not considered here.

The Dickson-type charge pump circuit described above steps up or steps down the input voltage Vi based on the clocks φ and φB which are opposite in phase to each other and outputted from the charge pump drive circuits 100A and 10B. The clocks φ and φB are generally rectangular waves. Accordingly, harmonic contents occur at rising edges and falling edges of pulses of these clocks, the harmonic contents are radiated as high frequency noises when the harmonic contents flows to the diodes Da to De as switching elements, and thus a wireless device (not shown) around the charge pump circuit is disturbed.

Japanese Laid Open Patent Application (JP-P2006-340436A) discloses art for reducing such spurious radiation due to the pulses of the clocks. A charge pump drive circuit described in Japanese Laid Open Patent Application (JP-P2006-340436A) includes a capacitor which is charged and discharged by two constant current sources, a control means for controlling charging and discharging periods of the capacitor, and an output means for outputting charge and discharge voltages of the capacitor as a clock φ to a charge pump circuit. In the charge pump drive circuit, charging and discharging of the capacitor are controlled such that periods of rising and falling of pulses of the clock φ are extended. Accordingly, it can be possible to blur the waveform of the clock φ at the rising and falling, and thus to suppress the occurrence of harmonic contents.

The present inventor has recognized as follows.

The charge pump drive circuit described in Japanese Laid Open Patent Application (JP-P2006-340436A) requires the constant current sources, the capacitor and the output means such as an operational amplifier in order to blur the waveform of the clock φ at the rising and falling, and requires switching elements in order to control the charge and discharge of the capacitor. Therefore, according to the charge pump drive circuit described in Japanese Laid Open Patent Application (JP-P2006-340436A), there is a problem of increasing in a size of a circuit and in a size of a chip.

### SUMMARY

In one embodiment, a charge pump drive circuit includes a first MOSFET (Metal Oxide Semiconductor Field Effect Transistor) and a second MOSFET. The first MOSFET and the second MOSFET are different in channel type and provided to form a complementary inverter circuit. The complementary inverter circuit drives a charge pump circuit based on an input potential inputted to an input terminal. A first gate of the first MOSFET and a second gate of the second MOSFET are connected to the input terminal such that a potential at the first gate is different from a potential at the second gate.

In another embodiment, a semiconductor device includes a charge pump circuit and a charge pump drive circuit. The charge pump drive circuit includes a first MOSFET (Metal Oxide Semiconductor Field Effect Transistor) and a second MOSFET. The first MOSFET and the second MOSFET are different in channel type and provided to form a complementary inverter circuit. The complementary inverter circuit drives the charge pump circuit based on an input potential inputted to an input terminal. A first gate of the first MOSFET and a second gate of the second MOSFET are connected to the input terminal such that a potential at the first gate is different from a potential at the second gate.

In another embodiment, a voltage converting method includes driving a charge pump circuit based on an input potential inputted to an input terminal. A first gate of a first MOSFET (Metal Oxide Semiconductor Field Effect Transistor) and a second gate of a second MOSFET are connected to the input terminal such that a potential at the first gate is different from a potential at the second gate. The first MOSFET and the second MOSFET are different in channel type and provided to form a complementary inverter circuit.

In the charge pump drive circuit, the semiconductor device and the voltage converting method, a high frequency noise which occurs in the charge pump circuit can be reduced while suppressing an increase in a circuit area.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram of a step-up circuit using a related charge pump drive circuit;

FIG. 2 is a circuit diagram of a step-up circuit using a charge pump drive circuit according to a first embodiment of the present invention;

FIG. 3 is a circuit diagram of a first constant current source circuit according to the first embodiment;

FIG. 4 is a circuit diagram of a second constant current source circuit according to the first embodiment; and

FIG. 5 is a timing chart showing relations among an input voltage of the charge pump drive circuit according to the first embodiment, voltages at gates of transistors of the circuit, and a clock outputted from the circuit.

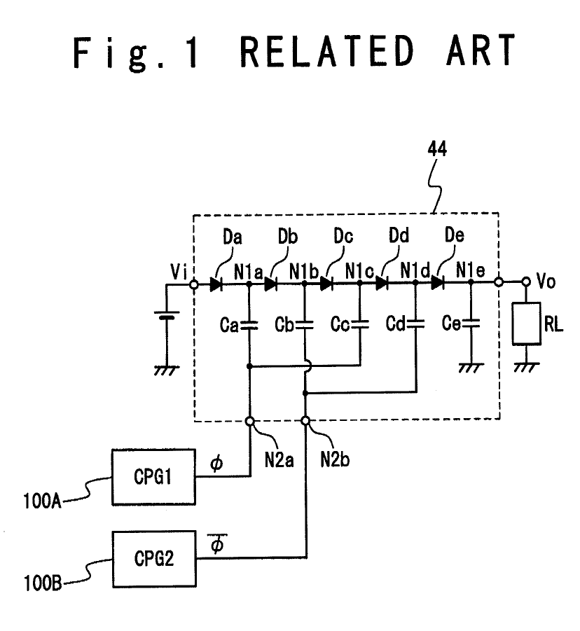

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

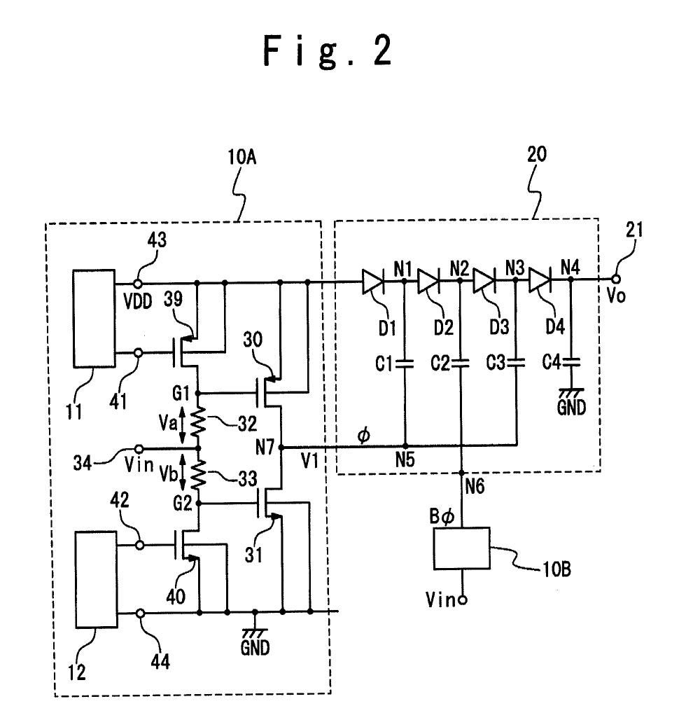

FIG. 2 is a circuit diagram of a semiconductor device according to a first embodiment of the present invention. In the present embodiment, a step-up circuit for stepping up a power source voltage VDD to an output voltage which is four times as large as the power source voltage VDD is described as an example of a circuit of the semiconductor device.

### (Configuration)

Referring to FIGS. 2 to 4, the semiconductor device (the step-up circuit) according to the present embodiment will be explained. Referring to FIG. 2, the semiconductor device according to the present embodiment includes charge pump drive circuits 10A and 10B, and a charge pump circuit 20. The charge pump drive circuits 10A and 10B output clocks and B to the charge pump circuit 20, respectively. The clocks φ and φB are clock pulse signals and the signal levels of the clocks φ and φB are periodically shifted from one level to the other level based on an input potential Vin. The charge pump drive circuit 10B includes the same circuit as the charge pump circuit 10A and an inverter circuit connected to an output terminal of the charge pump drive circuit 10B. The output terminal of the charge pump drive circuit 10B corresponds to an output node N7 described bellow. For this reason, the clock φB is opposite in phase to the clock φ. The structure and operation of the charge pump drive circuit 10B is obvious from the description about the charge pump drive circuit 10A.

The charge pump circuit 20 includes four diodes D1 to D4 and capacitors C1 to C4. The diodes D1 to D4 are connected in series between an input terminal 43 and an output terminal 21. The three capacitors C1 to C3 are connected to anodes of the diodes D2 to D4 at respective one ends (or nodes N1 to N3). One end of the capacitor C4 is connected to a cathode of the diode D4 and the other end of the capacitor 4 is grounded (or connected to a second power source GND). The input terminal 43 is connected to a first power source VDD and the first power source VDD supplies a power source potential VDD (first power source potential) to the input terminal 43. In addition, a load circuit (not shown) is connected to the output terminal 21. The other ends of the capacitors C1 and C3 are commonly connected via a node N5 to the output node N7 of the charge pump drive circuit 10A. The charge pump drive circuit 10A inputs the clock 4 to the node N5. In addition, the other end of the capacitor C2 is connected to the charge pump drive circuit 10B via a node N6. The charge pump drive circuit 10B inputs the clock 4B to the node N6.

The charge pump drive circuit 10A includes a P-channel type MOSFET (Metal Oxide Semiconductor Field Effect Transistor) 30 and an N-channel type MOSFET 31. The P-channel type MOSFET 30 and the N-channel type MOSFET 31 may be referred to as a first MOSFET (or a first transistor) and a second MOSFET (or a second transistor), respectively. The P-channel type MOSFET 30 and the N-channel type MOSFET 31 are different in channel type and provided to form a complementary inverter circuit. The complementary drive circuit drives the charge pump circuit 20 based on the input potential Vin inputted to an input terminal 34. The charge pump drive circuit 10A further includes a resistance element 32, a resistance element 33, a first current source circuit 11, a second current source circuit 12, a P-channel type MOSFET 39, and an N-channel type MOSFET 40. The P-channel type MOSFET 39 and the N-channel type MOSFET 40 may be referred to as a P-channel type transistor and an N-channel type transistor, respectively. The resistance element 32 and the resistance element 33 may be referred to as a first resistance element and a second resistance element, respectively. The first current source circuit 11 and the second current source circuit 12 may be referred to as a first constant current source and a second constant current source. For example, the resistance elements 32 and 33 are resistors. The P-channel type MOSFET 39 is connected to the first current source circuit 11 via a terminal 41. The N-channel type MOSFET 40 is connected to the second current source circuit 12 via a terminal 42.

A drain of the P-channel type MOSFET 30 is connected to a drain of the N-channel type MOSFET 31 via the output node N7 from which the clock ¢ is outputted. A source and a substrate of the P-channel type MOSFET 30 are connected to the first power source VDD. A source and a substrate of the N-channel type MOSFET 31 are connected to the second power source GND. A first gate G1 as a gate of the P-channel type MOSFET 30 is connected to a drain of the P-channel type MOSFET 39. A second gate G2 as a gate of the N-channel type MOSFET 31 is connected to a drain of the N-channel type MOSFET 40. The first gate Gi and the second gate G2 are connected via the resistance elements 32 and 33.

The resistance element 32 is provided between the first gate G1 and the input terminal 34. One end of the resistance element 32 is connected to the input terminal 34 to which the input potential Vin is supplied, and the other end is connected to the first gate G1 and the drain of the P-channel type MOSFET 39. The resistance element 33 is provided between the second gate G2 and the input terminal 34. One end of the resistance element 33 is connected to the input terminal 34, and the other end is connected to the second gate G2 and the drain of the N-channel type MOSFET 40. The input terminal 34 is connected to the first gate G1 via the resistance element 32 and is connected to the second gate G2 via the resistance element 33. The first and second gates G1 and G2 are connected to the input terminal 34 such that a potential at the first gate G1 is different from a potential at the second gate G2.

A source and a substrate of the P-channel type MOSFET 39 are connected to the first power source VDD, and a gate of the P-channel type MOSFET 39 is connected to the first current source circuit 11 via the terminal 41. The P-channel type MOSFET 39 functions as a current mirror circuit for passing a current generated by the first current source 11 to the first gate G1.

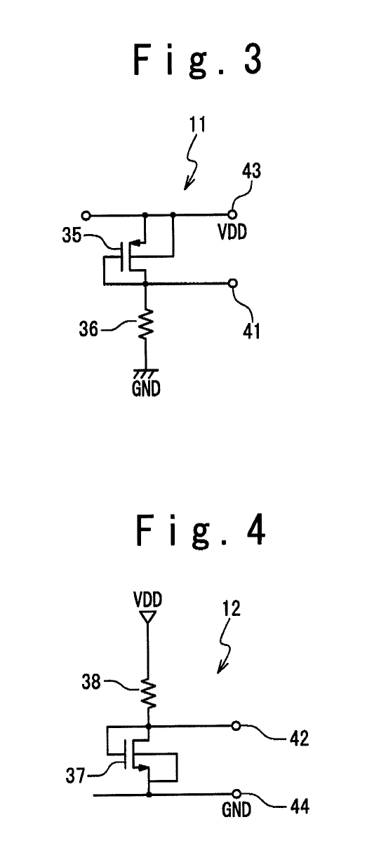

FIG. 3 is a circuit diagram of the first current source circuit 11. The first current source circuit 11 includes a P-channel type MOSFET 35 and a resistor 36. A source and a substrate of the P-channel type MOSFET 35 are connected to the first power source VDD (or the input terminal 43), and a gate and a drain of the P-channel type MOSFET 35 are connected to the terminal 41. One end of the resistor 36 is connected to the gate and the drain of the P-channel type MOSFET 35 (and to the terminal 41), and the other end is connected to the second power source GND. Accordingly, the first current source circuit 11 functions as a constant current source circuit for generating the current proportional to the power source voltage VDD supplied by the first power source VDD. The first current source circuit 11 supplies the current to the first gate G1 based on the power source voltage VDD (first power source voltage) corresponding to a difference (VDD−GND) between the power source potential VDD and a ground potential GND (second power source potential).

A source and a substrate of the N-channel type MOSFET 40 are connected to the second power source GND, and a gate of the N-channel type MOSFET 40 is connected to the second current source circuit 12 via the terminal 42. The N-channel type MOSFET 40 functions as a current mirror circuit for passing a current generated by the second current source 12 to the second gate G2.

FIG. 4 is a circuit diagram of the second current source circuit 12. The second current source circuit 12 includes an N-channel type MOSFET 37 and a resistor 38. A source and a substrate of the N-channel type MOSFET 37 are connected to the second power source GND, and a gate and a drain of the N-channel type MOSFET 37 are connected to the terminal 42. One end of the resistor 38 is connected to the gate and the drain of the N-channel type MOSFET 37 (and to the terminal 42), and the other end is connected to the first power source VDD (and to the input terminal 43). Accordingly, the second current source circuit 12 functions as a constant current source circuit for generating the current proportional to the power source voltage VDD supplied from the first power source VDD. The second current source circuit 12 supplies the current to the second gate G2 based on the power source voltage VDD (second power source voltage) corresponding to a difference (GND−VDD) between the power source potential VDD and the ground potential GND. The first and second power source voltages are opposite in sign and same in magnitude.

Other constant current sources can be employed as the current source circuits which are connected to the terminals 41 and 42 and shown in FIGS. 3 and 4.

### (Operation)

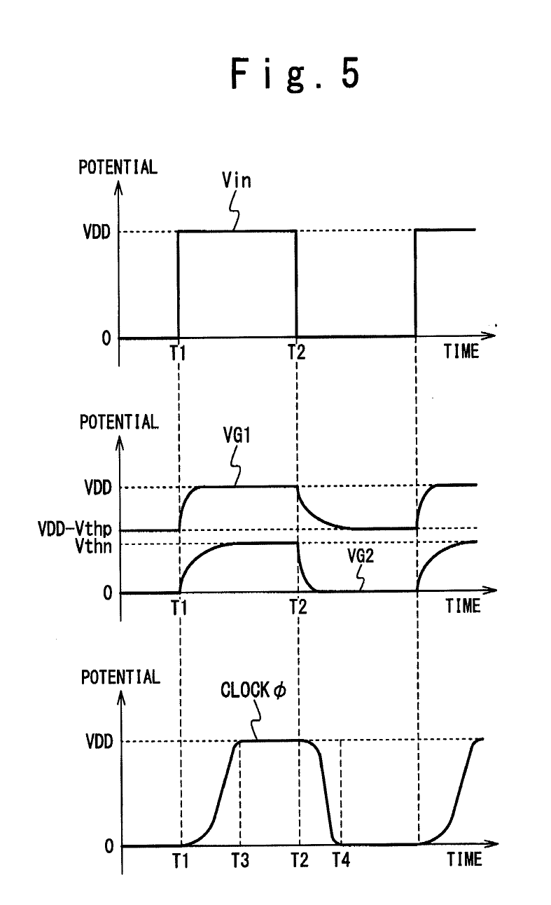

Referring to FIGS. 2 and 5, an operation of the semiconductor device (the step-up circuit) according to the present embodiment will be described. FIG. 5 is a timing chart showing the change of signal level of the input potential Vin inputted to the input terminal 34, the change of signal level of potential VG1 at the first gate G1, the change of signal level of potential VG2 at the second gate G2, and the change of signal level of the clock φ outputted from the output node N7.

Referring to FIG. 5, the input potential Vin is inputted to the input terminal 34 as a clock pulse waveform alternating between the power source potential VDD and the ground potential GND. The grand potential GND is 0[V].

From time 0 to time T1, the input potential Vin is equal to 0[V], and thus the potential VG1 is higher than the ground potential GND by a potential difference Va between the ends of the resistance element 32 due to a current passing the P-channel type MOSFET 39. The potential VG2 is equal to the ground potential GND from time 0 to time T1. It is preferable that the potential difference Va has a value equal to a difference VDD−Vthp obtained by subtracting a threshold voltage Vthp of the P-channel type MOSFET 30 from the power source voltage VDD when the input potential Vin is equal to 0[V]. In this case, the potential VG1 is lower than the power source potential VDD by the threshold voltage Vthp (VG1=VDD−Vthp). It is preferable that the potential difference Va is set to have the value which is based on the first power source voltage (VDD−GND) and the threshold voltage Vthp when the input potential Vin is equal to 0[V] (ground potential GND).

When the input potential Vin rises to the power source potential VDD at time T1, a voltage between the drain and the source of the P-channel type MOSFET 39 decreases gradually and the potential VG1 rises to reach the power source potential VDD. Immediately after rising of the input potential Vin, a current passing between the drain and the source of the P-channel type MOSFET 39 charges a gate capacitance of the P-channel type MOSFET 30 as an output buffer via the resistance element 32. For this reason, the potential VG1 rises to the power source potential VDD gradually compared to the rising of the input potential Vin.

When the input potential Vin falls to the ground potential GND (0[V]) at time T2, the voltage between the drain and the source of the P-channel type MOSFET 39 increases according to the falling of the input potential Vin and a current passes between the drain and the source. In addition, a charge charged in the gate capacitance of the P-channel type MOSFET 30 from time T1 to time T2 is drained via the resistance element 32 and the input terminal 34. A current as the flow of the charge drained from the first gate G1 is smaller than a current during the rising of the input potential Vin. Accordingly, the potential VG1 falls from VDD to VDD−Vthp gradually compared to the rising of the potential VG1 from VDD−Vthp to VDD.

The potential VG2 changes gradually according to the change of the signal level of the input potential Vin. To be more detailed, when the input potential Vin rises to the power source potential VDD at time T1, a voltage between the drain and the source of the N-channel type MOSFET 40 increases and a current passes between the drain and the source. The current between the drain and the source of the N-channel type MOSFET 40 charges a gate capacitance of the N-channel type MOSFET 31 as an output buffer via the resistance element 33. Since the gate capacitance is charged by the current which is reduced due to the resistance element 33 as described above, the potential VG2 rises gradually compared to the rising of the input voltage Vin. In addition, the potential VG2 rises to a potential (VDD−Vb) which is lower than the power source potential VDD by a potential difference Vb between both sides of the resistance element 33. The potential difference Vb is due to a current passing to the N-channel type MOSFET 40. It is preferable that the potential difference Vb has a value equal to a difference VDD−Vthn obtained by subtracting a threshold voltage Vthn of the N-channel type MOSFET 31 from the power source voltage VDD when the input potential Vin is equal to the power source potential VDD. In this case, the potential VG2 rises from 0[V] to Vthn (=VDD−Vb) gradually compared to the rising of the input potential Vin. It is preferable that the potential difference Vb is set to have the value which is based on the second power source voltage (GND−VDD) and the threshold voltage Vthn when the input potential Vin is equal to the power source potential VDD.

When the input potential Vin falls to the ground potential GND (0[V]) at time T2, the voltage between the drain and the source of the N-channel type MOSFET 40 decreases and a charge charged from time T1 to time T2 in the gate capacitance of the N-channel type MOSFET 30 is drained via the resistance element 33 and the input terminal 34. Accordingly, the potential VG2 falls from Vthn to 0[V] gradually compared to the falling of the input potential Vin.

As described above, when the input potential Vin falls to 0[V], the potential VG1 falls to VDD−Vthp gradually and the potential VG2 falls to 0[V] gradually. Thus, a resistance of the N-channel type MOSFET 31 gradually increases and the N-channel type MOSFET 31 becomes OFF state (non-conduction state). A resistance of the P-channel type MOSFET 30 gradually decreases and the P-channel type MOSFET 30 becomes ON state (conduction state). Accordingly, the potential at the output node N7 (the potential (or signal level) of the clock φ) falls to 0[V] gradually. In addition, when the input potential Vin rises to the power source potential VDD, the resistance of the N-channel type MOSFET 31 gradually decreases and the N-channel type MOSFET 31 becomes ON state. The resistance of the P-channel type MOSFET 30 gradually increases and the P-channel type MOSFET 30 becomes OFF state, when the input potential Vin rises to the power source potential VDD. Thus, the potential at the output node N7 (the potential of the clock φ) rises to the power source potential VDD gradually. Therefore, according to the present embodiment, when rectangular wave with a pulse width T2−T1 is inputted as the input potential Vin to the input terminal 34, rectangular wave with the rising being delayed from time T1 to time T3 and the falling being delayed from time T2 to time T3 is obtained as the clock φ.

A buffer circuit according to the related art, in which there is no potential difference between gates, converts a signal having a waveform with gradual rising edges and gradual falling edges into a rectangular signal with steep rising edges and steep falling edges. On the other hand, in the charge pump circuits 10A and 10B, there is a potential difference between the gates of the P-channel type MOSFET 30 and the N-channel type MOSFET 31 which function as a buffer for outputting the clock φ. For this reason, it is obvious that a maximum value of a through current flowing from the power source VDD to the ground GND through the P-channel type MOSFET 30 and the N-channel type MOSFET 31 is small and the through current rises and falls gradually. Furthermore, by setting the potential difference of the resistance element 32 as the potential difference (VDD−Vthp) obtained by subtracting the threshold voltage Vthp from the power source voltage and setting the potential difference of the resistance element 33 as the potential difference (VDD−Vthn) obtained by subtracting the threshold voltage Vthn from the power source voltage, the charge pump drive circuits 10A and 10B can output the clock φ with gradual rising edges and gradual falling edges both when the rising edges and the falling edges of the signal inputted to the input terminal 34 are steep and when the rising edges and the falling edges are gradual.

As described above, the charge pump drive circuits 10A can output the clock φ such that the timing of the shift of the signal level of the clock φ is delayed from the timing of the shift of the signal level of the input potential Vin. The charge pump drive circuits 10B can output the clock φB such that the timing of the shift of the signal level of the clock φB is delayed from the timing of the shift of the signal level of the input potential Vin. Accordingly, the occurrence of harmonic contents at the rising and falling in the clocks φ and φB inputted to the charge pump circuit 20 can be suppressed, and thus the radiation of the high frequency noise from the diodes D1 to D4 can be reduced.

In addition, different from the case of Japanese Laid Open Patent Application (JP-P2006-340436A), the charge pump drive circuits 10A and 10B according to the present embodiment does not require a capacitor and a switching element for blurring the waveforms of the clocks φ and φB at the rising and falling, and thus can output the clocks φ and φB with the gradual rising and falling edges while suppressing an increase in a circuit area. That is, according to the present embodiment, the occurrence of the harmonic contents in the charge pump circuit at the rising and the falling of the pulses of the clock are suppressed by the circuit having a smaller size than before.

It is apparent that the present invention is not limited to the above embodiments, but may be modified and changed without departing from the scope and spirit of the invention.

For Example, a diode or a transistor such as MOSFET may be used as each of the resistance elements 32 and 33 to provide the potential difference between the gates of the P-channel type MOSFET 30 and the N-channel type MOSFET 31. A plurality of diodes or transistors connected in series may be used as each of the resistance element 32 and 33.

The charge pump drive circuits 10A and 10B can be used for a step-down circuit.

Each of the charge pump drive circuits 10A and 10B may includes only one group of a group of the constant current source 11, the resistance element 32 and the N-channel type MOSFET 39 which are connected to the first gate G1 and a group of the constant current source 12, the resistance element 33 and the P-channel type MOSFET 40 which are connected to the first gate G2.

What is claimed is:

1. A charge pump drive circuit comprising:
a first MOSFET (Metal Oxide Semiconductor Field Effect Transistor); and
a second MOSFET,
wherein said first MOSFET and said second MOSFET are different in channel type and provided to form a complementary inverter circuit,
said complementary inverter circuit drives a charge pump circuit based on an input potential inputted to an input terminal, and
a first gate of said first MOSFET and a second gate of said second MOSFET are connected to said input terminal such that a potential at said first gate is different from a potential at said second gate.

2. The charge pump drive circuit according to claim 1, further comprising:
a first resistance element provided between said first gate and said input terminal; and
a first constant current source configured to supply a current to said first gate based on a first power source voltage corresponding to a difference between a first power source potential and a second power source potential.

3. The charge pump drive circuit according to claim 2, further comprising:
a second resistance element provided between said second gate and said input terminal; and
a second constant current source configured to supply a current to said second gate based on a second power source voltage,
wherein said first power source voltage and said second power source voltage are opposite in sign and same in magnitude.

4. The charge pump drive circuit according to claim 3, wherein a potential difference between ends of said first resistance element is set to have a value which is based on a threshold voltage of said first MOSFET and said first power source voltage when said input potential is equal to said second power source potential, and
a potential difference between ends of said second resistance element is set to have a value which is based on a threshold voltage of said second MOSFET and said second power source voltage when said input potential is equal to said first power source potential.

5. The charge pump drive circuit according to claim 3, further comprising:
a P-channel type MOSFET connected to said first gate and an end of said first resistance element; and
an N-channel type MOSFET connected to said second gate and an end of said second resistance element,
wherein said N-channel type MOSFET functions as a current mirror circuit, and
said P-channel type MOSFET functions as a current mirror circuit.

6. The charge pump drive circuit according to claim 3, wherein each of said first resistance element and said second resistance element includes a transistor.

7. The charge pump drive circuit according to claim 3, wherein each of said first resistance element and said second resistance element includes a plurality of transistors connected in series.

8. The charge pump drive circuit according to claim 3, wherein each of said first resistance element and said second resistance element includes a diode.

9. The charge pump drive circuit according to claim 3, wherein each of said first resistance element and said second resistance element includes a plurality of diodes connected in series.

10. A semiconductor device comprising:
a charge pump circuit; and
a charge pump drive circuit,
wherein said charge pump drive circuit includes:
a first MOSFET (Metal Oxide Semiconductor Field Effect Transistor); and
a second MOSFET,
said first MOSFET and said second MOSFET are different in channel type and provided to form a complementary inverter circuit,
said complementary inverter circuit drives said charge pump circuit based on an input potential inputted to an input terminal, and
a first gate of said first MOSFET and a second gate of said second MOSFET are connected to said input terminal such that a potential at said first gate is different from a potential at said second gate.

11. A voltage converting method comprising:
driving a charge pump circuit based on an input potential inputted to an input terminal,
wherein a first gate of a first MOSFET (Metal Oxide Semiconductor Field Effect Transistor) and a second gate of a second MOSFET are connected to said input terminal such that a potential at said first gate is different from a potential at said second gate, and
said first MOSFET and said second MOSFET are different in channel type and provided to form a complementary inverter circuit.
